(19) United States
(12) Patent Application Publication
(10) Pub. No.: US 2026/0215347 A1
(43) Pub. Date: Jul. 23, 2026

(54) SEMICONDUCTOR DEVICE

(71) Applicant: Mitsubishi Electric Corporation, Tokyo (JP)

(72) Inventors: Tatsuya KAWASE, Tokyo (JP); Norikazu SAKAI, Tokyo (JP)

(73) Assignee: Mitsubishi Electric Corporation, Tokyo (JP)

(21) Appl. No.: 19/141,309

(22) PCT Filed: Mar. 15, 2023
(86) PCT No.: PCT/JP2023/010033

§ 371 Date: Jun. 19, 2025

(51) Int. Cl. H10W 90/00; H10D 80/20; H10W 72/30

(52) U.S. Cl. CPC H10W 90/736; H10D 80/251; H10W 72/387; H10W 90/756

(57) ABSTRACT

A gate signal bonding material and a main current bonding material are separate from each other. The gate signal bonding material is disposed over an entire surface closer to a first gate signal circuit pattern of a first gate signal electrode. The main current bonding material is disposed over an entire surface closer to a first main current circuit pattern of a first main current electrode. A bonding area between the gate signal bonding material and the first gate signal electrode is smaller than a bonding area between the main current bonding material and the first main current electrode. The gate signal bonding material is formed into a rectangular shape in top view. Lengths a and b of two adjacent sides of the rectangular shape of the gate signal bonding material are each equal to or greater than twice a thickness c of the gate signal bonding material.

### TECHNICAL FIELD

The present disclosure relates to semiconductor devices.

BACKGROUND ART

A semiconductor device capable of suppressing poor bonding between a semiconductor element and a wiring layer and reduction in efficiency of cooling of the semiconductor element has been proposed.

As such a semiconductor device, Patent Document 1 discloses a power module including: a semiconductor element including an emitter electrode and a gate electrode formed in a back surface thereof; a columnar first electrode terminal having one end connected to the emitter electrode; a columnar second electrode terminal having one end connected to the gate electrode; and a circuit board including wiring layers bonded to the other end of the first electrode terminal and the other end of the second electrode terminal, for example.

### PRIOR ART DOCUMENTS

### Patent Document

Patent Document 1: Japanese Patent Application Laid-Open No. 2014-7366

### SUMMARY

### Problem To Be Solved By The Invention

In technology disclosed in Patent Document 1, however, the first electrode terminal and the second electrode terminal contributing to cooling are respectively only in contact with a portion of the emitter electrode and a portion of the gate electrode of the semiconductor element, so that the area of contact between them is small. Thermal diffusion of the semiconductor element is thus insufficient, and heat dissipation might be reduced.

While copper or a copper alloy is selected as materials for the first electrode terminal and the second electrode terminal in terms of heat conduction, copper and the copper alloy have high rigidity to raise concern about damage to the semiconductor element during a reliability test. Reliability of the semiconductor device thus might be reduced.

It is thus an object of the present disclosure to provide a semiconductor device capable of improving heat dissipation and reliability.

### Means To Solve The Problem

A semiconductor device according to the present disclosure includes: an insulating substrate including an insulating material, a first gate signal circuit pattern and a first main current circuit pattern formed over a front surface of the insulating material, and a back surface circuit pattern formed over a back surface of the insulating material; a semiconductor element mounted over the insulating substrate, the semiconductor element including a first gate signal electrode and a first main current electrode formed in a back surface thereof; a gate signal bonding material disposed between the first gate signal electrode and the first gate signal circuit pattern to bond the first gate signal electrode and the first gate signal circuit pattern; and a main current bonding material disposed between the first main current electrode and the first main current circuit pattern to bond the first main current electrode and the first main current circuit pattern, wherein the gate signal bonding material and the main current bonding material are separate from each other, the gate signal bonding material is disposed over an entire surface closer to the first gate signal circuit pattern of the first gate signal electrode, the main current bonding material is disposed over an entire surface closer to the first main current circuit pattern of the first main current electrode, a bonding area between the gate signal bonding material and the first gate signal electrode is smaller than a bonding area between the main current bonding material and the first main current electrode, and the gate signal bonding material is formed into a rectangular shape in top view, and lengths of two adjacent sides of the rectangular shape of the gate signal bonding material are each equal to or greater than twice a thickness of the gate signal bonding material.

### EFFECTS OF THE INVENTION

According to the present disclosure, the gate signal bonding material is disposed over the entire surface closer to the first gate signal circuit pattern of the first gate signal electrode formed in the back surface of the semiconductor element, and the main current bonding material is disposed over the entire surface closer to the first main current circuit pattern of the first main current electrode formed in the back surface of the semiconductor element, so that heat dissipation of the semiconductor device can be improved.

The bonding area between the gate signal bonding material and the first gate signal electrode is smaller than the bonding area between the main current bonding material and the first main current electrode, and the lengths of the two adjacent sides of the rectangular shape of the gate signal bonding material are each equal to or greater than twice the thickness of the gate signal bonding material, so that deformation due to a fall of the gate signal bonding material is less likely to occur to stabilize the thickness of the gate signal bonding material. This can suppress a tilt of the semiconductor element during a reliability test to improve reliability of the semiconductor device.

These and other objects, features, aspects and advantages of the present disclosure will become more apparent from the following detailed description when taken in conjunction with the accompanying drawings.

### BRIEF DESCRIPTION OF DRAWINGS

FIG. 1 is a top view of a semiconductor device according to Embodiment 1.

FIG. 2 is a cross-sectional view taken along the line A-A of FIG. 1.

FIG. 3 is a top view of a semiconductor device according to Embodiment 2.

FIG. 4 is a cross-sectional view taken along the line B-B of FIG. 2.

FIG. 5 is a top view of a semiconductor device according to Embodiment 3.

FIG. 6 is a top view of a semiconductor device according to Embodiment 4.

FIG. 7 is a cross-sectional view taken along the line C-C of FIG. 6.

FIG. 8 is a top view of a semiconductor device according to Embodiment 5.

FIG. 9 is a cross-sectional view taken along the line D-D of FIG. 7.

### DESCRIPTION OF EMBODIMENTS

### Embodiment 1

### Configuration of Semiconductor Device

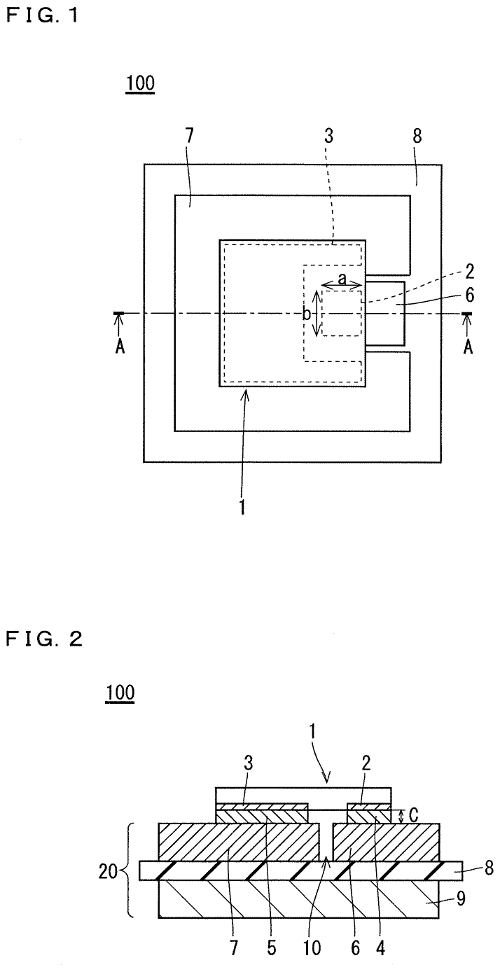

Embodiment 1 will be described below with reference to the drawings. FIG. 1 is a top view of a semiconductor device 100 according to Embodiment 1. FIG. 2 is a cross-sectional view taken along the line A-A of FIG. 1.

As illustrated in FIGS. 1 and 2, the semiconductor device 100 includes an insulating substrate 20, a semiconductor element 1, a gate signal bonding material 4, and a main current bonding material 5.

The insulating substrate 20 includes an insulating material 8, a first gate signal circuit pattern 6, a first main current circuit pattern 7, and a back surface circuit pattern 9.

The insulating material 8 is formed of an insulating resin or a ceramic. The insulating resin contains an epoxy resin as a major component, for example. The ceramic contains Al₂O₃, Si₃N₄, or AlN as a major component, for example. The insulating material 8 is required to have heat dissipation and thus generally desirably has high heat conductivity and a small thickness. An excessively small thickness of the insulating material 8, however, raises concern about an insufficient dielectric strength and a lack of a structural strength (e.g., stress resistance) during manufacture, so that the insulating material 8 desirably has a thickness of 100 μm or more.

The first gate signal circuit pattern 6 and the first main current circuit pattern 7 are formed over a front surface of the insulating material 8, and a gap 10 is formed between the first gate signal circuit pattern 6 and the first main current circuit pattern 7. The back surface circuit pattern 9 is formed over a back surface of the insulating material 8.

The first gate signal circuit pattern 6, the first main current circuit pattern 7, and the back surface circuit pattern 9 are formed of metal, such as aluminum, an aluminum alloy, copper, and a copper alloy. The first gate signal circuit pattern 6, the first main current circuit pattern 7, and the back surface circuit pattern 9 are located immediately below the semiconductor element 1 and have functions to diffuse heat generated by the semiconductor element 1. Thus, the first gate signal circuit pattern 6, the first main current circuit pattern 7, and the back surface circuit pattern 9 each desirably have a sufficient thickness to sufficiently diffuse heat in a planar direction (lateral direction) and each desirably have a thickness of 0.4 mm or more although it depends on a layout in the planar direction (lateral direction).

The semiconductor element 1 is formed of Si, SiC, GaN, or the like and is mounted over the insulating substrate 20. The semiconductor element 1 is an insulated gate bipolar transistor (IGBT) or a metal oxide semiconductor field effect transistor (MOSFET), for example. The semiconductor element 1 may be a reverse conducting IGBT (RC-IGBT) including an IGBT and a diode integrated with each other.

A first gate signal electrode 2 and a first main current electrode 3 are formed in a back surface of the semiconductor element 1. The first main current electrode 3 is formed into a U-shape in top view and occupies a major portion of the back surface of the semiconductor element 1. The first gate signal electrode 2 is formed into a rectangular shape in top view and is disposed between opposite end portions of the first main current electrode 3.

The first gate signal electrode 2 and the first main current electrode 3 are respectively bonded to the gate signal bonding material 4 and the main current bonding material 5 and are thus formed of highly wettable metal films of Ni, Au, Cu, Ag, or the like.

For example, when the semiconductor element 1 is an IGBT, the first gate signal electrode 2 is a gate electrode, and the first main current electrode 3 is an emitter electrode or a collector electrode. When the semiconductor element 1 is a MOSFET, the first gate signal electrode 2 is a gate electrode, and the first main current electrode 3 is a source electrode or a drain electrode.

Although not illustrated in FIG. 1, wires or electrodes to draw a gate signal and a main current are arranged over a front surface of the semiconductor element 1.

The gate signal bonding material 4 is disposed between the first gate signal electrode 2 and the first gate signal circuit pattern 6 to bond the first gate signal electrode 2 and the first gate signal circuit pattern 6. The main current bonding material 5 is disposed between the first main current electrode 3 and the first main current circuit pattern 7 to bond the first main current electrode 3 and the first main current circuit pattern 7. The gate signal bonding material 4 and the main current bonding material 5 are separate from each other and are spaced apart from each other. The gate signal bonding material 4 and the main current bonding material 5 are formed of lead-free solder containing Sn as a major component or a sintered material containing Ag or Cu as a major component.

The gate signal bonding material 4 is disposed over an entire surface closer to the first gate signal circuit pattern 6 of the first gate signal electrode 2. Similarly, the main current bonding material 5 is disposed over an entire surface closer to the first main current circuit pattern 7 of the first main current electrode 3. Thermal diffusion of the semiconductor element 1 is thereby secured.

An area in top view of the first gate signal electrode 2 is smaller than an area in top view of the first main current electrode 3, so that a bonding area between the first gate signal electrode 2 and the gate signal bonding material 4 is smaller than a bonding area between the first main current electrode 3 and the main current bonding material 5. Lengths a and b of two adjacent sides of the rectangular shape of the gate signal bonding material 4 are each equal to or greater than twice a thickness c of the gate signal bonding material 4. This suppresses deformation due to a fall of the gate signal bonding material 4 during a reliability test of the semiconductor device 100 to stabilize the thickness e of the gate signal bonding material 4.

### Method of Manufacturing Semiconductor Device

A method of manufacturing the semiconductor device 100 will briefly be described next. The insulating substrate 20 including the insulating material 8, the first gate signal circuit pattern 6 and the first main current circuit pattern 7 formed over the front surface of the insulating material 8, and the back surface circuit pattern 9 formed over the back surface of the insulating material 8 is prepared, and the semiconductor element 1 is mounted over the insulating substrate 20. Specifically, the semiconductor element 1 is disposed so that the first gate signal electrode 2 and the first gate signal circuit pattern 6 oppose each other and the first main current electrode 3 and the first main current circuit pattern 7 oppose each other. In this case, the semiconductor element 1 generates greater heat on a side of the emitter electrode in a case of the IGBT and on a side of the source electrode in a case of the MOSFET, so that, when the first main current electrode 3 is the emitter electrode or the source electrode, heat generated by the semiconductor element 1 can more efficiently be cooled.

When the semiconductor element 1 is mounted, the gate signal bonding material 4 is disposed between the first gate signal electrode 2 and the first gate signal circuit pattern 6, and the main current bonding material 5 is disposed between the first main current electrode 3 and the first main current circuit pattern 7. They are bonded in a required atmosphere and at a required temperature and a required pressure. The wires or the electrodes to draw the gate signal and the main current are finally bonded to the front surface of the semiconductor element 1 to complete the semiconductor device 100.

### Effects

As described above, the semiconductor device 100 according to Embodiment 1 includes: the insulating substrate 20 including the insulating material 8, the first gate signal circuit pattern 6 and the first main current circuit pattern 7 formed over the front surface of the insulating material 8, and the back surface circuit pattern 9 formed over the back surface of the insulating material 8; the semiconductor element 1 mounted over the insulating substrate 20, the semiconductor element 1 including the first gate signal electrode 2 and the first main current electrode 3 formed in the back surface thereof; the gate signal bonding material 4 disposed between the first gate signal electrode 2 and the first gate signal circuit pattern 6 to bond the first gate signal electrode 2 and the first gate signal circuit pattern 6; and the main current bonding material 5 disposed between the first main current electrode 3 and the first main current circuit pattern 7 to bond the first main current electrode 3 and the first main current circuit pattern 7. The gate signal bonding material 4 and the main current bonding material 5 are separate from each other, and the gate signal bonding material 4 is disposed over the entire surface closer to the first gate signal circuit pattern 6 of the first gate signal electrode 2. The main current bonding material 5 is disposed over the entire surface closer to the first main current circuit pattern 7 of the first main current electrode 3. The bonding area between the gate signal bonding material 4 and the first gate signal electrode 2 is smaller than the bonding area between the main current bonding material 5 and the first main current electrode 3, and the gate signal bonding material 4 is formed into the rectangular shape in top view, and the lengths a and b of the two adjacent sides of the rectangular shape of the gate signal bonding material 4 are each equal to or greater than twice the thickness c of the gate signal bonding material 4.

The gate signal bonding material 4 is disposed over the entire surface closer to the first gate signal circuit pattern 6 of the first gate signal electrode 2 formed in the back surface of the semiconductor element 1, and the main current bonding material 5 is disposed over the entire surface closer to the first main current circuit pattern 7 of the first main current electrode 3 formed in the back surface of the semiconductor element 1, so that heat dissipation of the semiconductor device 100 can be improved.

The bonding area between the gate signal bonding material 4 and the first gate signal electrode 2 is smaller than the bonding area between the main current bonding material 5 and the first main current electrode 3, and the lengths a and b of the two adjacent sides of the rectangular shape of the gate signal bonding material 4 are each equal to or greater than twice the thickness c of the gate signal bonding material 4, so that deformation due to the fall of the gate signal bonding material 4 is less likely to occur to stabilize the thickness of the gate signal bonding material 4. This can suppress a tilt of the semiconductor element 1 during the reliability test to improve reliability of the semiconductor device 100. In view of the foregoing, reduction in size and improvement in yield of the semiconductor device 100 can be achieved.

Since the insulating material 8 is formed of the insulating resin or the ceramic, a difference in coefficient of linear expansion between the insulating substrate 20 and the semiconductor element 1 is small. Stress applied to the semiconductor element 1 by expansion and contraction of the insulating substrate 20 during the reliability test is thus suppressed even when the semiconductor element 1 is mounted to span the first gate signal circuit pattern 6 and the first main current circuit pattern 7. As a result, reliability of the semiconductor device 100 can further be improved.

### Embodiment 2

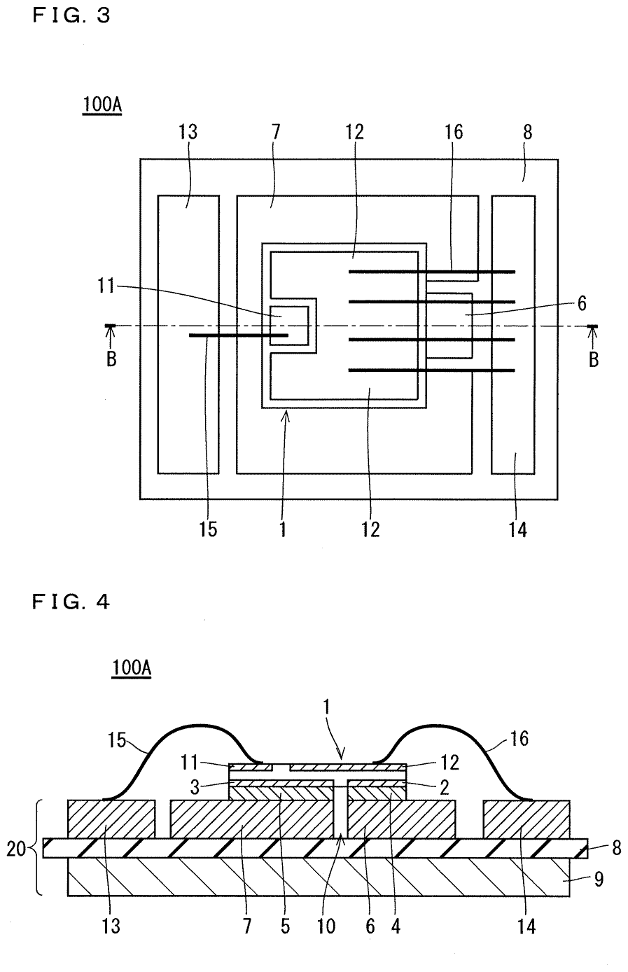

A semiconductor device 100A according to Embodiment 2 will be described next. FIG. 3 is a top view of the semiconductor device 100A according to Embodiment 2. FIG. 4 is a cross-sectional view taken along the line B-B of FIG. 2. In Embodiment 2, the same components as those described in Embodiment 1 bear the same reference signs as those of the same components, and description thereof is omitted.

As illustrated in FIGS. 3 and 4, in Embodiment 2, the semiconductor element 1 further includes a second gate signal electrode 11 and a second main current electrode 12 formed in the front surface thereof. The insulating material 8 further includes a second gate signal circuit pattern 13 and a second main current circuit pattern 14 formed over the front surface thereof.

The second main current electrode 12 is formed into a U-shape in top view and occupies a major portion of the front surface of the semiconductor element 1. The second gate signal electrode 11 is formed into a rectangular shape in top view and is disposed between opposite end portions of the second main current electrode 12.

For example, when the semiconductor element 1 is the IGBT, the first gate signal electrode 2 is the gate electrode. The first main current electrode 3 is the emitter electrode, and the second main current electrode 12 is the collector electrode. When the semiconductor element 1 is the MOSFET, the first gate signal electrode 2 is the gate electrode. The first main current electrode 3 is the source electrode, and the second main current electrode 12 is the drain electrode.

Signal wiring 15 is disposed to electrically connect the second gate signal electrode 11 and the second gate signal circuit pattern 13. Similarly, main current wiring 16 is disposed to electrically connect the second main current electrode 12 and the second main current circuit pattern 14. A point of connection between the signal wiring 15 and the second gate signal electrode 11 is located above the first main current circuit pattern 7. Specifically, the point of connection is in contact with the first main current circuit pattern 7 via the semiconductor element 1 and the main current bonding material 5. A point of connection between the main current wiring 16 and the second main current electrode 12 is located above the first main current circuit pattern 7. Specifically, the point of connection is in contact with the first main current circuit pattern 7 via the semiconductor element 1 and the gate signal bonding material 4.

### Effects

As described above, in the semiconductor device 100A according to Embodiment 2, the semiconductor element 1 further includes the second gate signal electrode 11 and the second main current electrode 12 formed in the front surface thereof. Carrier control can thus be performed in the front surface and the back surface of the semiconductor element 1 to reduce loss (heat generation) of the semiconductor element 1. As a result, reliability of the semiconductor device 100A can be improved compared with that in a case of Embodiment 1.

The insulating material 8 further includes the second gate signal circuit pattern 13 and the second main current circuit pattern 14 formed over the front surface thereof. The semiconductor device 100A further includes the signal wiring 15 to connect the second gate signal electrode 11 and the second gate signal circuit pattern 13 and the main current wiring 16 to connect the second main current electrode 12 and the second main current circuit pattern 14. The point of connection between the signal wiring 15 and the second gate signal electrode 11 is located above the first main current circuit pattern 7, and the point of connection between the main current wiring 16 and the second main current electrode 12 is located above the first main current circuit pattern 7.

A temperature rise at these points of connection is thus suppressed when the semiconductor device 100A is energized, so that reliability of the semiconductor device 100A can further be improved.

The semiconductor element 1 includes the IGBT or the MOSFET, the first main current electrode 3 is the emitter electrode or the source electrode, and the second main current electrode 12 is the collector electrode or the drain electrode.

Thus, in a direction of a thickness of the semiconductor element 1, the emitter electrode or the source electrode, which generates greater heat, is disposed closer to the circuit pattern, so that the semiconductor element 1 can efficiently be cooled. As a result, reliability of the semiconductor device 100A can be improved.

### Embodiment 3>

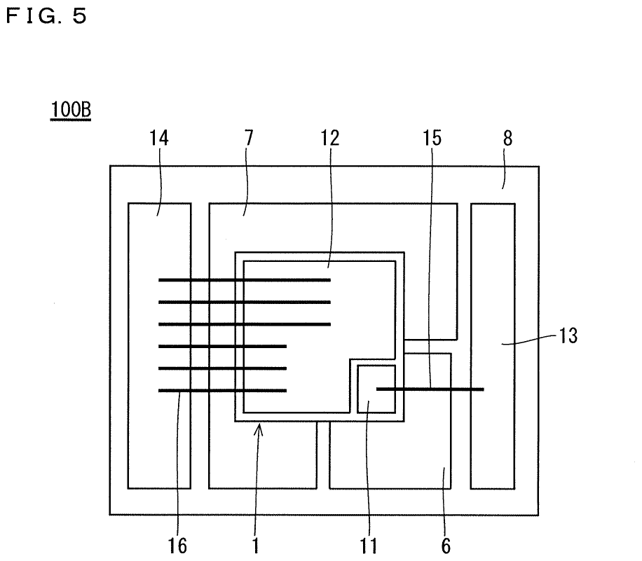

A semiconductor device 100B according to Embodiment 3 will be described next. FIG. 5 is a top view of the semiconductor device 100B according to Embodiment 3. In Embodiment 3, the same components as those described in Embodiments 1 and 2 bear the same reference signs as those of the same components, and description thereof is omitted.

In Embodiment 2, the second main current electrode 12 is disposed to overlap each of the first main current circuit pattern 7 and the first gate signal circuit pattern 6 in top view. In contrast, in Embodiment 3, as illustrated in FIG. 5, the second main current electrode 12 is disposed to overlap only the first main current circuit pattern 7 and does not overlap the first gate signal circuit pattern 6 in top view.

The second gate signal electrode 11 is disposed in one of four corners (a lower right corner in FIG. 5) in the front surface of the semiconductor element 1. The first gate signal electrode 2 is disposed at a location corresponding to the second gate signal electrode 11. The first gate signal electrode 2 is thus disposed in one of four corners (a lower right corner in FIG. 5) in the back surface of the semiconductor element 1. The first gate signal electrode 2 is only required to be disposed in any one of four corners of the semiconductor element 1, and a location of the first gate signal electrode 2 can be changed according to a location of the first gate signal circuit pattern 6 and a location of the second gate signal circuit pattern 13.

### Effects

As described above, in the semiconductor device 100B according to Embodiment 3, the second main current electrode 12 and the first main current circuit pattern 7 are arranged to overlap each other in top view. While the second main current electrode 12, from which a current is drawn, generates greater heat, heat from the second main current electrode 12 generating greater heat can efficiently be cooled, so that reliability of the semiconductor device 100B can be improved.

The first gate signal electrode 2 is disposed in any one of the four corners of the semiconductor element 1. A lifetime of a bonding material bonded to the back surface of the semiconductor element 1 is often limited by crack propagation from the four corners of the semiconductor element 1. In Embodiment 3, a thickness of the gate signal bonding material 4 bonded to any one of the four corners in the back surface of the semiconductor element 1 is stabilized. A thickness of a bonding material bonded to the other three corners in which the first gate signal electrode 2 is not disposed in the back surface of the semiconductor element 1 is thereby also stabilized, so that reliability of the semiconductor device 100B can be improved.

### Embodiment 4

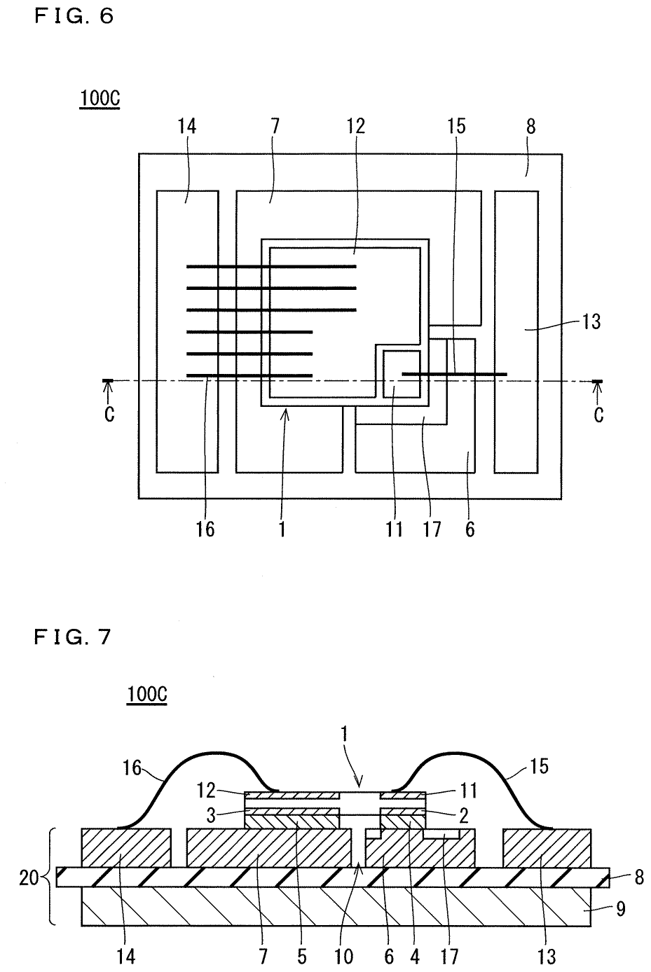

A semiconductor device 100C according to Embodiment 4 will be described next. FIG. 6 is a top view of the semiconductor device 100C according to Embodiment 4. FIG. 7 is a cross-sectional view taken along the line C-C of FIG. 6. In Embodiment 4, the same components as those described in Embodiments 1 to 3 bear the same reference signs as those of the same components, and description thereof is omitted.

As illustrated in FIGS. 6 and 7, in Embodiment 4, an obstructer 17 is formed over the first gate signal circuit pattern 6 relative to the configuration according to Embodiment 3. The obstructer 17 is provided to obstruct wetting spread of the gate signal bonding material 4 and is formed over the first gate signal circuit pattern 6 to surround a portion of bonding of the gate signal bonding material 4. The obstructer 17 may be formed of a resin-based material, such as a resist, and may be a roughened portion having a rougher surface than the other portion over the first gate signal circuit pattern 6.

### Effects

In the semiconductor device 100C according to Embodiment 4, the obstructer 17 to obstruct wetting spread of the gate signal bonding material 4 is formed over the first gate signal circuit pattern 6 to surround the portion of bonding of the gate signal bonding material 4. A shape of the gate signal bonding material 4 is thereby stabilized to stabilize the thickness of the gate signal bonding material 4. As a result, reliability of the semiconductor device 100C can be improved.

The obstructer 17 is formed of the resin-based material. The resin-based material having properties to repel the gate signal bonding material 4 can obstruct wetting spread of the gate signal bonding material 4.

The obstructer 17 is the roughened portion having the rougher surface than the other portion over the first gate signal circuit pattern 6, so that wetting spread of the gate signal bonding material 4 can be obstructed. A material of a different type, such as the resin-based material, is not used to suppress incompatibility between the obstructer 17 and a portion around the obstructer 17.

### Embodiment 5

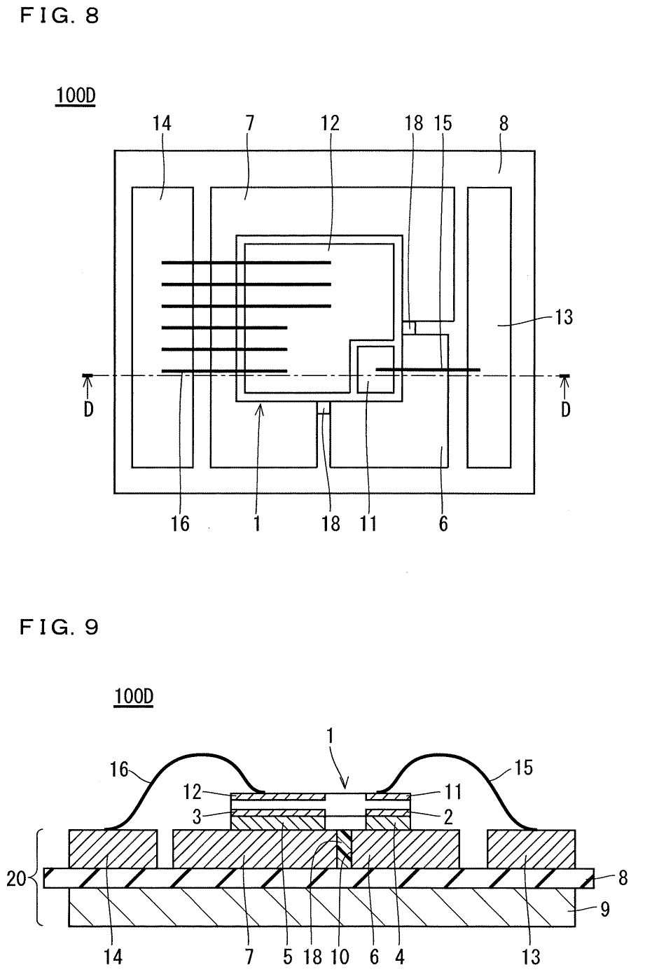

A semiconductor device 100D according to Embodiment 5 will be described next. FIG. 8 is a top view of the semiconductor device 100D according to Embodiment 5. FIG. 9 is a cross-sectional view taken along the line D-D of FIG. 7. In Embodiment 5, the same components as those described in Embodiments 1 to 4 bear the same reference signs as those of the same components, and description thereof is omitted.

In Embodiment 4, the obstructer 17 is formed over the first gate signal circuit pattern 6 to surround the portion of bonding of the gate signal bonding material 4. In contrast, in Embodiment 5, as illustrated in FIGS. 8 and 9, the gap 10 is filled with an obstructer 18. The obstructer 18 is formed of the resin-based material, such as the resist. Specifically, the obstructer 18 is formed in the gap 10 to surround a portion of bonding of the gate signal bonding material 4. The gap 10 according to Embodiment 4 can be filled with the obstructer 18.

### Effects

As described above, in the semiconductor device 100D according to Embodiment 5, the gap 10 is formed between the first gate signal circuit pattern 6 and the first main current circuit pattern 7, and the obstructer 18 to obstruct wetting spread of the gate signal bonding material 4 is disposed in the gap 10. Ingress of the gate signal bonding material 4 into the gap 10 can thereby be suppressed to stabilize the thickness of the gate signal bonding material 4. As a result, reliability of the semiconductor device 100B can be improved.

While the present disclosure has been described in detail, the foregoing description is in all aspects illustrative and not restrictive. It is understood that numerous unillustrated modifications can be devised.

Embodiments can freely be combined with each other and can be modified or omitted as appropriate.

### EXPLANATION OF REFERENCE SIGNS

1 semiconductor element, 2 first gate signal electrode, 3 first main current electrode, 4 signal bonding material, 5 main current bonding material, 6 first gate signal circuit pattern, 7 first main current circuit pattern, 8 insulating material, 9 back surface circuit pattern, 10 gap, 11 second gate signal electrode, 12 second main current electrode, 13 second gate signal circuit pattern, 14 second main current circuit pattern, 15 signal wiring, 16 main current wiring, 17, 18 obstructer, 20 insulating substrate.

1. A semiconductor device comprising:
an insulating substrate including an insulating material, a first gate signal circuit pattern and a first main current circuit pattern formed over a front surface of the insulating material, and a back surface circuit pattern formed over a back surface of the insulating material;
a semiconductor element mounted over the insulating substrate, the semiconductor element including a first gate signal electrode and a first main current electrode formed in a back surface thereof;
a gate signal bonding material disposed between the first gate signal electrode and the first gate signal circuit pattern to bond the first gate signal electrode and the first gate signal circuit pattern; and
a main current bonding material disposed between the first main current electrode and the first main current circuit pattern to bond the first main current electrode and the first main current circuit pattern, wherein
the gate signal bonding material and the main current bonding material are separate from each other,
the gate signal bonding material is disposed over an entire surface closer to the first gate signal circuit pattern of the first gate signal electrode,
the main current bonding material is disposed over an entire surface closer to the first main current circuit pattern of the first main current electrode,
a bonding area between the gate signal bonding material and the first gate signal electrode is smaller than a bonding area between the main current bonding material and the first main current electrode, and
the gate signal bonding material is formed into a rectangular shape in top view, and lengths of two adjacent sides of the rectangular shape of the gate signal bonding material are each equal to or greater than twice a thickness of the gate signal bonding material.

2. The semiconductor device according to claim 1, wherein the insulating material is formed of an insulating resin or a ceramic.

3. The semiconductor device according to claim 1, wherein
the semiconductor element further includes a second gate signal electrode and a second main current electrode formed in a front surface thereof.

4. The semiconductor device according to claim 3, wherein the insulating substrate further includes a second gate signal circuit pattern and a second main current circuit pattern formed over the front surface of the insulating material,
the semiconductor device further comprises
signal wiring to connect the second gate signal electrode and the second gate signal circuit pattern and main current wiring to connect the second main current electrode and the second main current circuit pattern,
a point of connection between the signal wiring and the second gate signal electrode is located above the first main current circuit pattern, and
a point of connection between the main current wiring and the second main current electrode is located above the first gate signal circuit pattern.

5. The semiconductor device according to claim 3, wherein
the second main current electrode and the first main current circuit pattern are arranged to overlap each other in top view.

6. The semiconductor device according to claim 1, wherein
the first gate signal electrode is disposed in any one of four corners of the semiconductor element.

7. The semiconductor device according to claim 1, wherein
an obstructer to obstruct wetting spread of the gate signal bonding material is formed over the first gate signal circuit pattern to surround a portion of bonding of the gate signal bonding material.

8. The semiconductor device according to claim 1, wherein
a gap is formed between the first gate signal circuit pattern and the first main current circuit pattern, and
an obstructer to obstruct wetting spread of the gate signal bonding material is disposed in the gap.

9. The semiconductor device according to claim 7, wherein
the obstructer is formed of a resin-based material.

10. The semiconductor device according to claim 7, wherein
the obstructer is a roughened portion having a rougher surface than the other portion over the first gate signal circuit pattern.

11. The semiconductor device according to claim 3, wherein
the semiconductor element includes an IGBT or a MOSFET,
the first main current electrode is an emitter electrode or a source electrode, and
the second main current electrode is a collector electrode or a drain electrode.
